(19) United States
(12) Patent Application Publication
(10) Pub. No.: US 2021/0111359 A1
(43) Pub. Date: Apr. 15, 2021

(54) SHORTWAVE INFRARED ORGANIC PHOTODIODE WITH AN INCREASED DIELECTRIC CONSTANT

(71) Applicant: THE REGENTS OF THE UNIVERSITY OF CALIFORNIA, Oakland, CA (US)

(72) Inventors: Tse Nga Ng, San Diego, CA (US); Zhenghui Wu, San Diego, CA (US)

(21) Appl. No.: 16/956,035

(22) PCT Filed: Dec. 20, 2018
(86) PCT No.: PCT/US2018/066962

§ 371 Date: Jun. 19, 2020

Related U.S. Application Data
(60) Provisional application No. 62/608,559, filed on Dec. 20, 2017.
(60) Provisional application No. 62/745,271, filed on Oct. 12, 2018.

(51) Int. Cl. H01L 51/42; H01L 51/44; H01L 51/00

(52) U.S. Cl. CPC H01L 51/4253; H01L 51/0034; H01L 51/0047; H01L 51/442

(57) ABSTRACT

Embodiments of a shortwave infrared organic photodiode (IR) are disclosed. The IR includes a substrate layer. The IR includes a first electrode layer, the first electrode layer disposed on the substrate layer. The IR includes a first interfacial layer, the first interfacial layer disposed on the first electrode layer. The IR includes a bulk heterojunction, the bulk heterojunction disposed on the first interfacial layer. The bulk heterojunction may include an additive with a dielectric constant above a threshold value. The IR includes a second interfacial layer, the second interfacial layer disposed on the bulk heterojunction. The IR includes a second electrode layer, the second electrode layer disposed on the second interfacial layer.

### CROSS-REFERENCE TO RELATED APPLICATIONS

The present application is a U.S. National Phase under 35 U.S.C. § 371 of International Application No. PCT/US2018/066962, filed Dec. 20, 2018, titled “SHORTWAVE INFRARED ORGANIC PHOTODIODE WITH AN INCREASED DIELECTRIC CONSTANT” which claims the benefit of priority to U.S. Provisional Application No. 62/608,559, filed on Dec. 20, 2017, and entitled “Shortwave Infrared Organic Photodiode With An Increased Dielectric Constant”, and U.S. Provisional Application No. 62/745,271, filed on Oct. 12, 2018, and entitled “Role Of Dielectric Screening In Organic Shortwave Infrared Photodiodes For Spectroscopic Image Sensing” the content of which are hereby incorporated by reference in their entirety.

### TECHNICAL FIELD

The present disclosure is generally related to organic photodiodes. More particularly, some embodiments of the present disclosure relate to infrared (IR) organic photodiodes with an increased dielectric constant to increase photogeneration.

### BACKGROUND

Photodiodes, which are commonly used for photogeneration, convert light into electrical currents. When light impinges upon a photodiode, an electron-hole pair may be created. The built-in electric field in the depletion region of the photodiode separates electrons and holes on opposite sides of the region, which creates a photocurrent. Thus, photodiodes are a powerful tool for solar energy, infrared imaging, spectroscopy, and optoelectronics.

Currently, most organic photodiodes operate in the visible wavelength because of the large bandgap that allows for efficient exciton dissociation. For IR organic photodiodes, the dissociation process may be a limiting factor in improving efficiency. As a result, typical IR organic photodiodes may have an external quantum efficiency (EQE) below 20%.

### BRIEF SUMMARY OF THE EMBODIMENTS

Embodiments of the systems and methods disclosed herein may incorporate high dielectric-constant (k) or relative permittivity (εᵣ) materials in the bulk heterojunction (BHJ). This may have the effect of increasing the photocurrent of an organic photodiode, because the higher dielectric constant screens charge and stabilizes free carriers and improves dissociation of charge-transfer excitons in organic BHJ. For example, by adding camphoric acid anhydrate (CA), which has a high dielectric constant greater than or equal to about 4 compared to typical pristine organic materials with dielectric constants less than about 4, the organic IR photodiode performance may be improved to EQE of about 26%. Organic photodiodes with CA as an additive in the BHJ perform better than the photodiodes without CA. Moreover, alternatives to CA may also be used. For example, another approach to high-k materials may include using polarizable ethylene-glycol side-chains attached to the donor or acceptor materials, in place of the conventional non-polar alkyl side-chains.

The dielectric constant or permittivity, εᵣ, may represent the polarizability of a material. Increasing polarizability may offer a path to screen Coulombic interactions between electron-hole pairs and stabilize free carriers. The BHJ permittivity may be increased by adding camphoric anhydride, which is an insulating molecule with one of the highest permittivities among organic solids (εᵣ is about 24).

In some embodiments, a IR organic photodiode may include a substrate layer. The IR organic photodiode may include a first electrode layer. The first electrode layer may be disposed on the substrate layer. The IR organic photodiode may include a first interfacial layer. The first interfacial layer may be disposed on the first electrode layer. The IR organic photodiode may include a bulk heterojunction. The bulk heterojunction may be disposed on the first interfacial layer. The bulk heterojunction may include an additive with a dielectric constant above a threshold value. The IR organic photodiode may include a second interfacial layer. The second interfacial layer may be disposed on the bulk heterojunction. The IR organic photodiode may include a second electrode layer. The second electrode layer may be disposed on the second interfacial layer.

In embodiments, the additive may be one or more of an organic material, dissolvable in a polymer solution, and an insulator or a semiconductor.

In embodiments, the additive may be camphoric acid anyhdrate.

In embodiments, the amount of additive used in the bulk heterojunction may be between about 5% to about 25% by weight.

In embodiments, the amount of additive used in the bulk heterojunction may be between about 10% to about 15% by weight.

In embodiments, the bulk heterojunction may further include a donor polymer and an acceptor.

In embodiments, the donor polymer may include sulfur.

In embodiments, the donor polymer may include selenium.

In embodiments, the acceptor molecules may include a fullerene-derivative PCBM.

In embodiments, the donor polymer may include a side chain of ethylene glycol.

In embodiments, a relative permittivity value for the bulk heterojunction is greater than or equal to about 4.

In some embodiments, a IR organic photodiode may include a bulk heterojunction. The bulk heterojunction may include an additive with a dielectric constant above a threshold value. The bulk heterojunction may include a donor polymer. The bulk heterojunction may include an acceptor.

In embodiments, the additive may be one or more of an organic material, dissolvable in a polymer solution, and an insulator or a semiconductor.

In embodiments, the additive may be camphoric acid anyhdrate.

In embodiments, the amount of additive used in the bulk heterojunction may be between about 5% to about 25% by weight.

In embodiments, the amount of additive used in the bulk heterojunction may be between about 10% to about 15% by weight.

In embodiments, the donor polymer may include sulfur.

In embodiments, the donor polymer may include selenium.

In embodiments, the acceptor molecules may include a fullerene-derivative PCBM.

In embodiments, the donor polymer may include a side chain of ethylene glycol.

In embodiments, a relative permittivity value for the bulk heterojunction is greater than or equal to about 4.

In other embodiments, a IR organic photodiode may include a substrate layer; a first interfacial layer, the first interfacial layer attached to the top side of the substrate layer; a BHJ, the BHJ disposed on the first layer, wherein the BHJ includes polarizable sidechains to attach to the BHJ to achieve improved efficiencies; a second interfacial layer, the second interfacial layer attached to a top side of the BHJ; and an electrode layer, the electrode layer disposed on the second interfacial layer.

Other features and aspects of the disclosed technology will become apparent from the following detailed description, taken in conjunction with the accompanying drawings, which illustrate, by way of example, the features in accordance with embodiments of the disclosed technology. The summary is not intended to limit the scope of any inventions described herein, which are defined solely by the claims attached hereto.

### BRIEF DESCRIPTION OF THE DRAWINGS

Various embodiments are disclosed herein and described in detail with reference to the following figures. The drawings are provided for purposes of illustration only and merely depict typical or example embodiments of the disclosed technology. These drawings are provided to facilitate the reader's understanding of the disclosed technology and shall not be considered limiting of the breadth, scope, or applicability thereof. It should be noted that for clarity and ease of illustration these drawings are not necessarily made to scale.

FIG. 1A illustrates a structure of a IR organic photodiode in accordance with one embodiment of the technology described herein.

FIG. 1B illustrates additives that may be used in a photodiode in accordance with one embodiment of the technology described herein.

FIG. 1C illustrates non-polar and polarizable side-chains in accordance with one embodiment of the technology described herein.

FIG. 2A is a plot illustrating the dark current density and voltage for example photodiodes.

FIG. 2B is a plot illustrating EQE and wavelength for example photodiodes.

FIG. 3 is a plot illustrating photocurrent and voltage for example photodiodes.

FIG. 4 is a plot illustrating EQE of example photodiodes and incident wavelength.

FIG. 5 is a plot illustrating photocurrent density and voltage for example photodiodes.

FIG. 6A is a plot illustrating intensity and Q vector for example BHJ films.

FIG. 6B is a plot illustrating intensity and Q vector for example BHJ films.

FIG. 6C is a plot of patterns of BHJ films with example photodiodes

FIG. 7A is a plot illustrating normalized transient photocurrent and time for example photodiodes.

FIG. 7B is a plot illustrating photoconductivity density and time for example photodiodes.

FIG. 7C is a plot illustrating initial carrier concentration and applied voltage for example photodiodes.

FIG. 8 is a table illustrating parameters for photodiodes with different BHJ compositions.

FIG. 9A is a plot illustrating real impedance and imaginary impedance and time for example photodiodes.

FIG. 9B is a plot illustrating imaginary impedance and frequency for example photodiodes.

FIG. 9C is a plot illustrating capacitance and frequency for example photodiodes.

FIG. 9D is a plot illustrating density of states and energy from the band edge for example photodiodes.

FIG. 10 illustrates an example effect of dielectric screening.

FIG. 11 is a plot illustrating specific detectivity and incident light wavelength for example photodiodes.

FIG. 12A illustrates an example transmittance spectra of muscle and fatty tissues.

FIG. 12B illustrates an example measurement setup, in accordance with various embodiments of the present disclosure.

FIG. 12C illustrates percentage of fatty tissue at each pixel location.

The figures are not intended to be exhaustive or to limit the invention to the precise form disclosed. It should be understood that the invention can be practiced with modification and alteration, and that the disclosed technology be limited only by the claims and the equivalents thereof.

### DETAILED DESCRIPTION OF THE EMBODIMENTS

Photodetection in the infrared (IR, including near and shortwave, uses wavelengths from about 0.75 to about 1 μm and about 1 to about 3 μm, respectively) forms the foundation for many spectroscopic systems and medical applications. For the next generation of IR detectors, solution-processed semiconductors offer the potential to achieve scalable integrated arrays while significantly lowering processing costs. Existing solution-processed polymers may be able to extend the spectral response of organic bulk heterojunction (BHJ) photodiodes out to about 2 μm. However, the device's external quantum efficiency (EQE) remains low when operating without photoconductive gain, with EQE less than or equal to about 15% in existing organic IR photodiodes. The presently disclosed technology discloses an additive approach that enhances dielectric screening and can double the device EQE in multiple, different IR BHJs.

Embodiments of the systems and methods disclosed herein relate to IR organic photodiode systems and methods that can be used in a variety of applications including, for example, photovoltaic devices. The IR spectrum may be from about 0.75 to about 3 μm.

More particularly, embodiments may be implemented using materials to provide an increased dielectric constant within the BHJ of the device to achieve improved efficiencies. In some embodiments, the efficiencies achieved may be above about 20%, while in further embodiments, the EQE may be about 26%. The additive approach may increase dielectric screening in organic IR photodiodes. Dielectric screening may reduce the exciton binding energy to increase exciton dissociation efficiency and lower trap-assisted recombination loss, in the absence of any morphological changes. In some embodiments, the exciton binding energy is E_{B}=q²/(4πε₀εᵣa), dependent on the internal electron-hole pair delocalization distance, a, and the surrounding permittivity, εᵣ, while ε₀ is the permittivity of vacuum. In embodiments, a peak internal quantum efficiency (IQE) at about 1100 nm may be increased up to about 66%, and the photoresponse may extend to about 1400 nm. As will be described herein, the IR photodiodes may be integrated into a 4×4 pixel imager to demonstrate tissue differentiation and estimate the fat-to-muscle ratio through noninvasive spectroscopic analysis.

Embodiments may be implemented that use camphoric acid anhydrate (CA) to increase the dielectric constant of the BHJ. For example, CA may be mixed into a polymer solution before spin coating the layer onto the device. CA may enhance the screening effect in the BHJ because the dipoles will interact with the photogenerated exciton, which consists of a bound electron-hole pair. With more dipoles, the excitons may become more stable and more likely to dissociate to produce photocurrent. In some embodiments, CA may have a dielectric constant greater than about 4. This is in contrast to the typical dielectric constant for IR organic photodiodes, which may be less than about 4. The amount of CA mixed into a polymer may be, for example, between about 5% to about 25% by weight of CA, although other concentrations may be used. It should be appreciated that other materials may be used as an additive that includes one or more of the following factors: an organic material, a material with a high dielectric constant, a material that can be dissolved in the polymer solution, a material that may be an insulator, a polarizable material, and other factors.

In various embodiments, the organic IR polymer may include one or more of OC₁₂-Flanked Qxc8, fullerene-derivative PC₇₀BM, and other polymers. For example, the ratio of blending OC₁₂-Flanked Qxc8 with fullerene-derivative PC₇₀BM may be about 1:2. It should be appreciated that the ratio of blending the polymers may vary. The two polymers may be dissolved in dichlorobenzene, chloroform, or other solvents.

In some embodiments, polarizable ethylene-glycol units may be added as side-chains attached to the donor- or acceptor-polymer materials. The amount of polarizable ethylene-glycol may be determined by the amount of alkyl units in a side-chain as well. The polarizable ethylene-glycol may have a similar screening effect as the CA does to the photodiode.

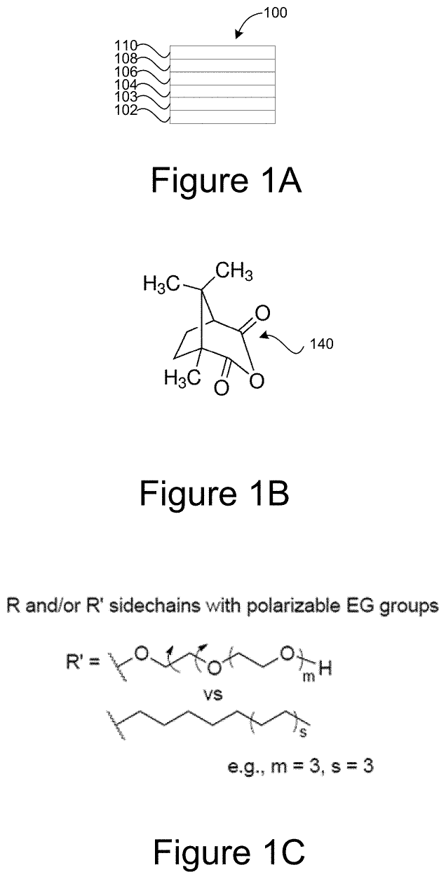

FIG. 1A is an illustration of a structure of a IR organic photodiode in accordance with one embodiment of the technology described herein. Although this example is described in terms of a photodiode, it should be appreciated that the systems and methods disclosed herein can be used with other technologies beyond photodiodes. In the illustrated example, IR organic photodiode 100 includes substrate layer 102, electrode layer 103, BHJ layer 106, electrode layer 110, and interfacial layers 104, 108. These layers may not be drawn to scale. In the illustrated example, electrode layer 103 may include, for example, a transparent conductive oxide such as, for example, indium tin oxide, indium-tin-oxide-coated glass, or another material. Interfacial layer 104 may be included to help transport holes. Interfacial layer 104 may include, for example, PEDOT:PSS CLEVIOS™ P VP AI 4083, or another material. In some embodiments, the thickness of interfacial layer 104 may be between about 10 nanometers to about 50 nanometers. The thickness of interfacial layer 104 may also be about 30 nanometers. In other embodiments, interfacial layer 104 may be of other thicknesses. In various embodiments, interfacial layer 104, BHJ 106, and interfacial layer 108 may be deposited sequentially by spin-coating. It should be appreciated that different processes may be used to couple, deposit, or otherwise incorporate the layers together.

BHJ 106 is disposed between interfacial layer 104 and interfacial layer 108. BHJ 106 may be a blend of electron-acceptor and -donor materials. BHJ 106 may include polymers, which, in some embodiments, may include one or more of OC₁₂-Flanked QxC8, fullerene-derivative PC₇₀BM, and other polymers and small molecules. The polymers may be dissolved in dichlorobenzene or other solvents. The thickness of BHJ 106 may be between about 150 nanometers to about 250 nanometers, although it can be other thicknesses. In some embodiments, the thickness of BHJ 106 may be about 190 nanometers. As noted above, CA may be added to BHJ 106 to increase its dielectric constant. In some embodiments, the amount of CA added to BHJ 106 may be about 5% to about 25% by weight of CA. In other embodiments, the amount of CA added to BHJ 106 may be about 10% to about 15% by weight of CA. CA is highly polar, while IR polymers and fullerenes are nonpolar molecules. The film morphology may be undistributed, and, in disordered BHJs, there may be free volume space to accommodate the additives. In embodiments, when the percentage of CA additive is increased beyond 27%, the BHJ morphology may be affected by the additive.

For example, FIG. 1B illustrates an example of materials that can be blended to create BHJ 106. This example includes polymers OC₁₂-Flanked QxC8 and fullerene-derivative PC₇₀BM. In some embodiments, these can be blended in a ratio of about 1:2 and dissolved in a dichlorobenzene solvent with a polymer concentration of about 7.5 mg/ml. FIG. 1B also illustrates a chemical structure of CA 140.

In some embodiments, polarizable ethylene-glycol may be added to the side-chains of the electron-acceptor and -donor materials. For example, FIG. 1C illustrates the chemical structure of polarizable ethylene-glycol attaching to the sidechains of donor or acceptor materials. R in FIG. 1C may include the oxyalkyl chain. R′ in FIG. 1C may include the alkyl chain. The amount of polarizable ethylene-glycol may be determined by the number of alkyl units in the side-chain.

Interfacial layer 108 may be a cathode interlayer that helps transport electrons. In some embodiments, interfacial layer 108 may include zinc oxide or other materials. In various embodiments, the thickness of interfacial layer 108 may be between about 5 nanometers to about 25 nanometers. In other embodiments, the thickness of interfacial layer 108 may be about 10 nanometers. Interfacial layer 108 may also be of other thicknesses.

Adjacent to interfacial layer 108 may be an electrode layer 110. In some embodiments, electrode layer 110 may include silver, aluminum, or other conductive materials. The electrode layer may be deposited by thermal evaporation or other deposition techniques.

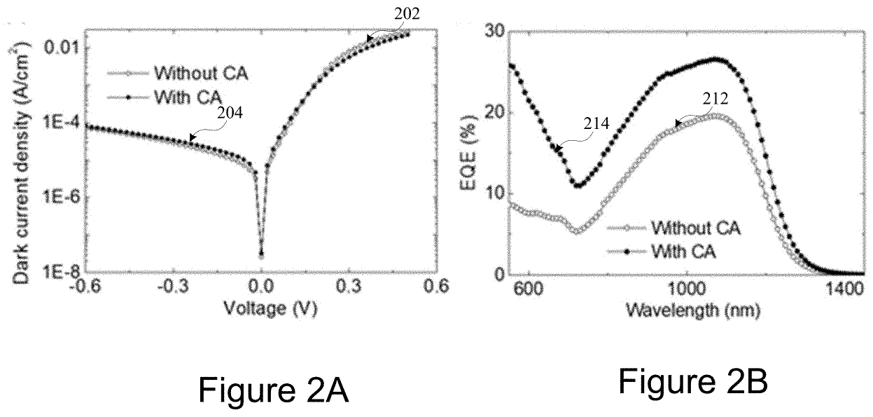

FIG. 2A is a plot illustrating the dark current density and voltage for example photodiodes. Curve 202 represents an example photodiode without CA. Curve 204 represents an example photodiode with CA. The amount of CA may be about 15% by weight.

FIG. 2B is a plot illustrating EQE and wavelength for example photodiodes. Curve 212 represents an example photodiode without CA. Curve 214 represents an example photodiode with CA. The amount of CA may be about 15% by weight. The EQE may be calculated with the expression EQE=R(hc/λq)=(Jₚₕ/Pᵢₗₗᵤₘᵢₙ)(hc/λq), where h may represent Planck's constant, c may represent the speed of light, λ may represent the wavelength of the incident light, q may represent the electron charge, Jₚₕ may represent the photocurrent density, Pᵢₗₗᵤₘᵢₙ may represent the intensity of the incident light, and R may represent the responsivity.

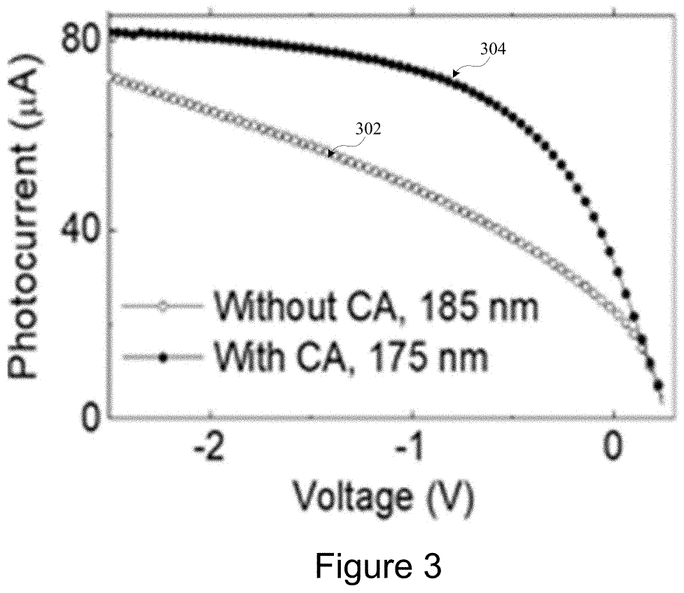

FIG. 3 is a plot illustrating photocurrent and voltage for example photodiodes. Curve 302 represents an example photodiode without CA. Curve 304 represents an example photodiode with CA. The amount of CA may be about 15% by weight.

The IR photodiode may include a donor-acceptor polymer including one or more of sulfur, C₁₂H₂₅, selenium, C₁₆H₂₃, and other materials. For example, polymer, P1, may include sulfur and C₁₂H₂₅. In some embodiments, another polymer, P2, may include selenium and C₁₆H₂₃. It should be appreciated that other molecules and elements may be used to synthesize different donor-acceptor polymers for different applications. P1 may differ from P2 by the thiophene and selenophene spacer and side-chain lengths. In some embodiments, P2 may have a narrower bandgap than P1.

CA may include one or more of H₃C, CH₃, and oxygen. It should be appreciated that other molecules and elements may be used to synthesize different additives for different applications. In embodiments, the amount of CA or additive may be about 15% by weight.

A fullerene acceptor may include one or more elements: oxygen, a methyl group element, carbon, etc. For example, fullerene acceptor may be a fullerene-derivative PCBM. It should be appreciated that other molecules and elements may be used to synthesize different fullerene acceptors for different applications. In embodiments, a donor-acceptor polymer, an additive , and a fullerene acceptor may be combined in a solution to create a IR photodiode. For example, BHJ blends may include a polymeric donor and a fullerene-derivative acceptor in about a 1:2 weight ratio and about 0 to about 15% by weight of the high-εᵣ additive. It should be appreciated that the ratio of polymeric donor to fullerene-derivative acceptor and the % weight may be different for different applications.

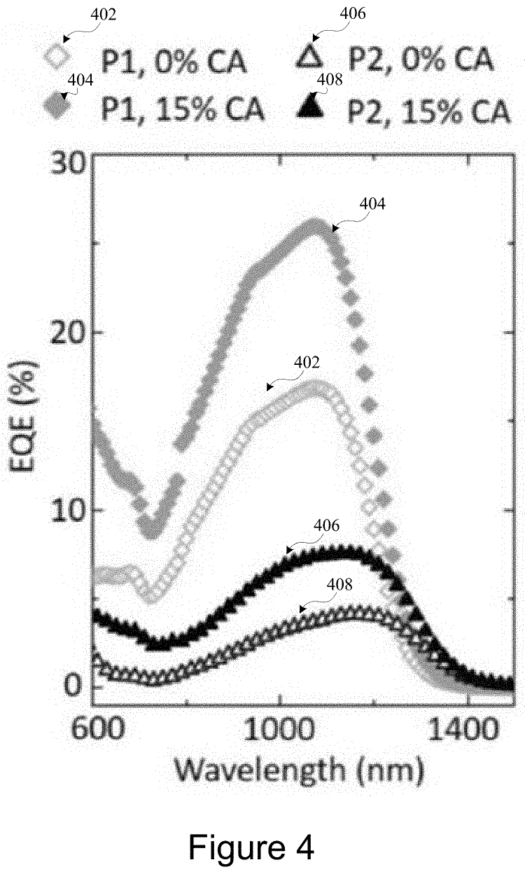

FIG. 4 is a plot illustrating EQE of example photodiodes and incident wavelength. Curve 402 represents P1 without CA. Curve 404 represents P1 with about 15% CA. Curve 406 represents P2 without CA. Curve 408 represents P2 with about 15% CA. In embodiments, EQE may be a product of the efficiencies of photon absorption, exciton dissociation, and charge collection: EQE=η_{absorb}η_{dissociate}η_{collect}.

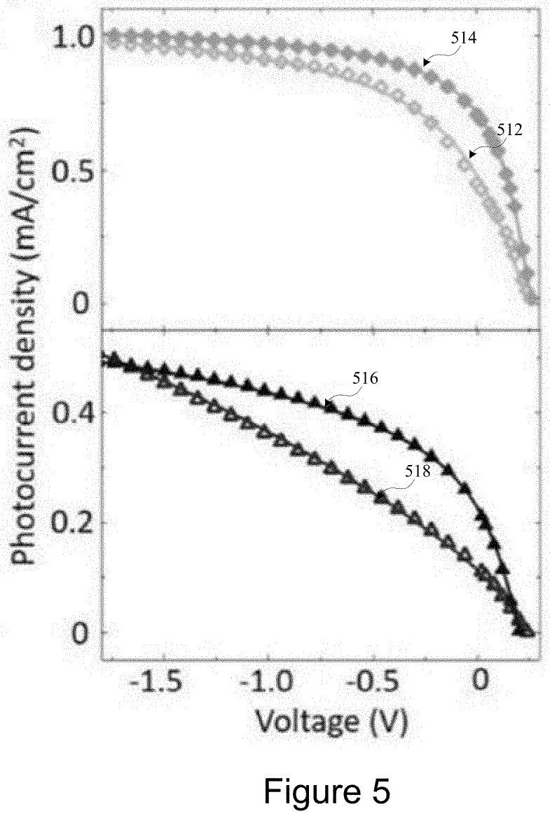

FIG. 5 is a plot illustrating photocurrent density and voltage for example photodiodes. The example photodiodes may have been under incident light with a wavelength of about 1100 nm and an intensity of about 3.2 mW cm⁻². Curve 512 represents P1 without CA. Curve 514 represents P1 with about 15% CA. Curve 516 represents P2 without CA. Curve 518 represents P2 with about 15% CA. Curves 512, 514, 516, and 518 may be fitted based on the following equation defining photocurrent density:

$$\begin{matrix}\begin{matrix}{J}_{phss} = {J}_{sat} {η}_{collect} ( {E}_{eff} ) {η}_{dissociate} ( {E}_{eff} ) with \\ {η}_{collect} ( {E}_{eff} ) = \frac{2 {μτE}_{eff}}{d} [ 1 - exp ( - \frac{d}{2 μτ {E}_{eff}} ) ] part a\end{matrix} \\ {η}_{dissociate} ( {E}_{eff} ) = \frac{4}{{a}^{3} \sqrt{π}} {\int }_{0}^{∞} \frac{{k}_{D}}{{k}_{D} + {k}_{R}} {x}^{2} exp ( - \frac{{x}^{2}}{{a}^{2}} ) dx part b\end{matrix}$$

The steady-state photocurrent density Jₚₕₛₛ may be a function of the effective electric field E_{eff}=V_{eff}/d. The parameter Jₛₐₜ may represent saturation current density dependent on incident light intensity, and Jₚₕₛₛ/Jₛₐₜ=IQE may represent the IQE that excludes the light absorption efficiency. For η_{collect}, the fit variable μτ may represent the mobility-lifetime product that characterizes the capture cross section and density of recombination centers. The λ_{dissociate} expression may be dependent on the rates of exciton dissociation k_{D} and recombination k_{R}. The exciton delocalization length, a, may be about 1.3 nm. It should be appreciated that different exciton delocalization lengths may be appropriate. The dissociation rate may be represented as

$${k}_{D} ( {E}_{eff} ) = \frac{3 q μ}{4 {πɛ}_{0} {ɛ}_{r} {a}^{3}} exp ( - \frac{{E}_{B}}{k T} ) [ 1 + b + … ] with$$

$$b = \frac{{q}^{3} {E}_{eff}}{8 {πɛ}_{0} {{ɛ}_{r} ( kT )}^{2}}$$

The variable may be the recombination rate k_{R}. Two variables, μτ and k_{R}, may be adjusted to obtain appropriate fits to the data as described above in FIG. 5. In embodiments, the fitting process may be simplified by the prior results from transient photoconductivity (TPC) measurements. For example, for P1 BHJs, the initial carrier density may be shown to be independent of electric field, indicating the dissociation efficiency is near 100%. The fits to P1 devices may not require part b of the photocurrent density equation above and may be reverted to a simple adjustment of a single variable to determine η_{collect}.

As illustrated in FIG. 5, the electric-field dependence may be reduced in the photocurrent of devices with CA. The photodiode with P1 and CA may have a peak EQE of about 26% at about 0 V bias and about 35% at about −1 V for wavelength of about 1100 nm.

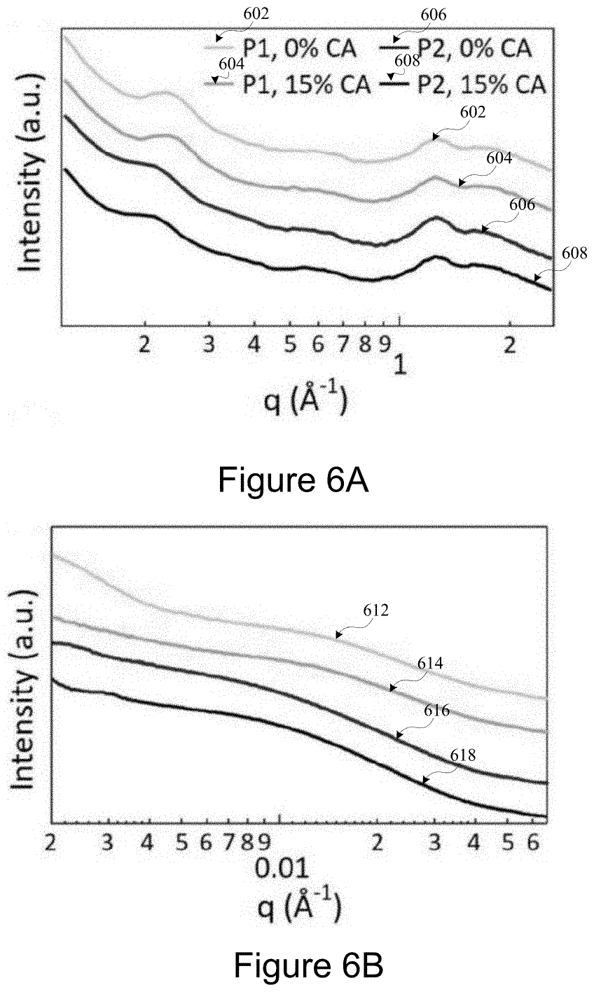

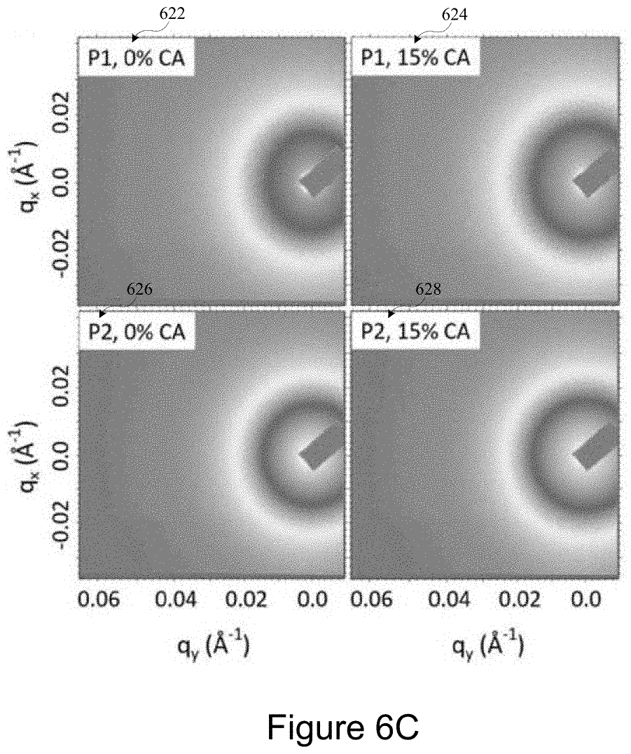

FIGS. 6A is a plot illustrating intensity and Q vector for example BHJ films. As illustrated, curves 602, 604, 606, and 608 represent line profiles of the scatter intensity and scattering vector of BHJ thing films in GIXD. Curve 602 represents P1 without CA. Curve 604 represents P1 with about 15% CA. Curve 606 represents P2 without CA. Curve 608 represents P2 with about 15% CA. The BHJ thin films illustrate broad diffraction peaks at q is about 1.26 Å⁻¹ which can be attributed to the scattering from amorphous PC₇₁BM and disordered polymer regions.

FIG. 6B is a plot illustrating intensity and Q vector for example BHJ films. Curves 612, 614, 616, and 618 represent line profiles of the scatter intensity and scattering vector of BHJ thing films in R-SoXS. Curve 612 represents P1 without CA. Curve 614 represents P1 with about 15% CA. Curve 616 represents P2 without CA. Curve 618 represents P2 with about 15% CA. Broad shoulders may be illustrated around 0.02 Å⁻¹ for the P1 BHJ. These shoulder may indicate the domain size of donor/acceptor phase segregation, which may be about 30 nm for films with P1. Broad shoulders in the scattering profiles may be illustrated at around 0.01 Å⁻¹ for the P2 BHJ. The domain size of donor/acceptor phase segregation may be about 60 nm for P2. The phase segregation may be about the same between films with or without CA.

FIG. 6C is a plot of patterns of BHJ films with example photodiodes. Plot 622 and plot 724 illustrate the patterns for a P1 polymer with and without CA. Plot 626 and plot 628 illustrate the patterns for a P2 polymer with and without CA. The amount of CA may be about 15% by weight.

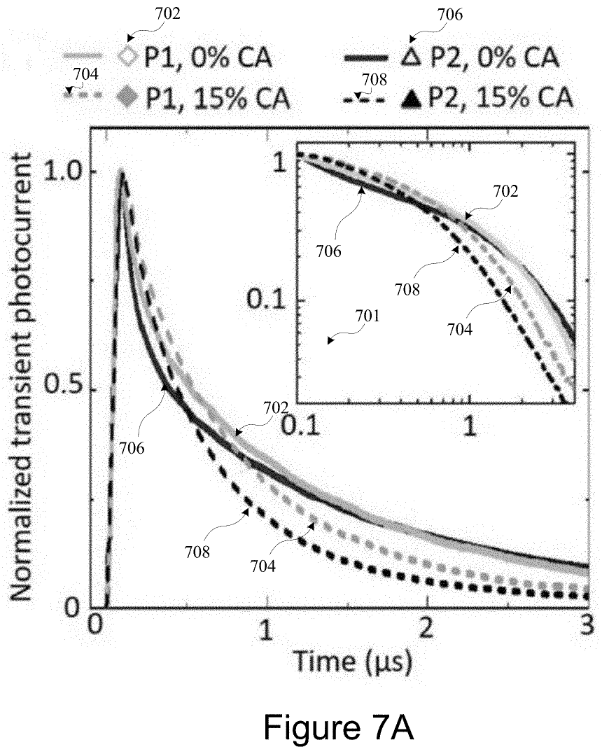

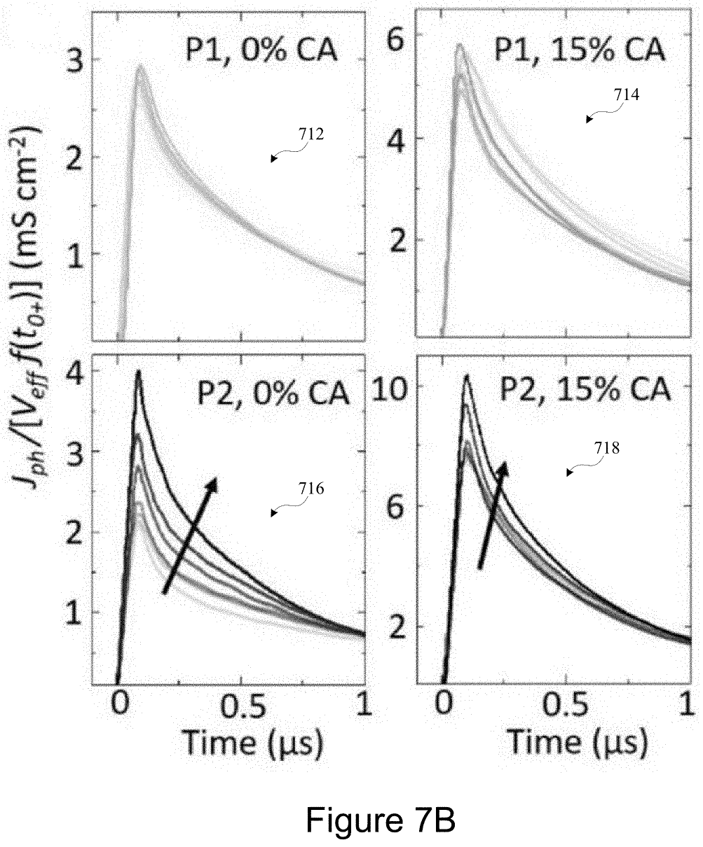

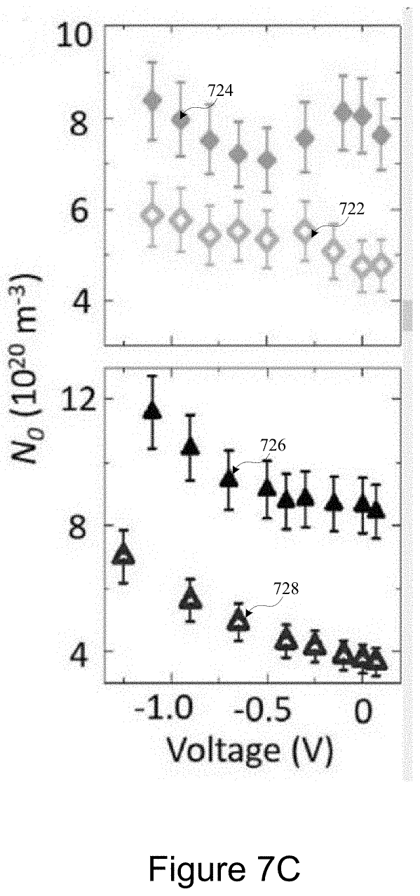

FIG. 7A is a plot illustrating normalized transient photocurrent and time for example photodiodes. Curves 702, 704, 706, and 708 represent P1 without CA, P1 with CA, P2 without CA, and P2 with CA, respectively. The amount of CA added may be about 15% by weight. The example photodiodes may have been subjected to about 0.1 V. Plot 701 may be the same data in a logarithmic scale. The ratio between values at TRC and at t₀₊ may be estimated to be a factor of f(t₀₊)=(1−τ_{TR}/τₜᵣₐₙₛᵢₜ)²

FIG. 7B is a plot illustrating photoconductivity density and time for example photodiodes. Plots 712, 704, 716, and 718 represent P1 without CA, P1 with CA, P2 without CA, and P2 with CA, respectively. The amount of CA added may be about 15% by weight. The multiple lines may represent an applied bias starting at about 0.1 V to about −1.5 V indicated by the arrow direction. Taking this factor of f(t₀₊) into account, as described above, the adjusted TPC densities may be displayed.

FIG. 7C is a plot illustrating initial carrier concentration and applied voltage for example photodiodes. Curves 722, 724, 726, and 728 represent P1 without CA, P1 with CA, P2 without CA, and P2 with CA, respectively. The amount of CA added may be about 15% by weight. The peak values in FIG. 7B may be converted into initial carrier densities. An initial carrier density may be calculated using

$${N}_{0} ( V ) = {J}_{p h} ( V , {τ}_{R C} ) \frac{d}{q} 〈 μ 〉 {V}_{eff} f ( {t}_{0 +} )$$

Curve 726 may illustrate the initial carrier density N₀ increased from about 4×1020 m⁻³ to about 7×1020 m⁻³, which is about a 75% change in N₀ due to the applied electric field. Curve 828 may illustrate N₀ increased by about 22% from about 9×1020 to about 11×1020 m⁻³ under the same electric field. The initial carrier density N(V, t₀₊) may be proportional to the transient photocurrent density, expressed as Jₚₕ(V, t₀₊)=q<μ>N(V, t₀₊) V_{eff}/d, where t₀₊ may represent a time just after the illumination pulse, q may represent an elementary charge, <μ> may represent an average mobility, d may represent a BHJ layer thickness, and V_{eff}=V_{bi}−V may represent an effective voltage from subtracting the applied voltage V from the built-in voltage V_{bi}.

As illustrated, the error bars may be generated by transit times, which may be the intersection point where the transient photoconductivity signal switches its slope as shown in FIG. 7A. The transit time τₜᵣₐₙₛᵢₜ is the intersection point where the TPC signal switches its slope.

FIGS. 7A, 7B, and 7C may indicate that the addition of CA has a greater effect on the CT exciton dissociation process in P2 but not as much in P1 blends.

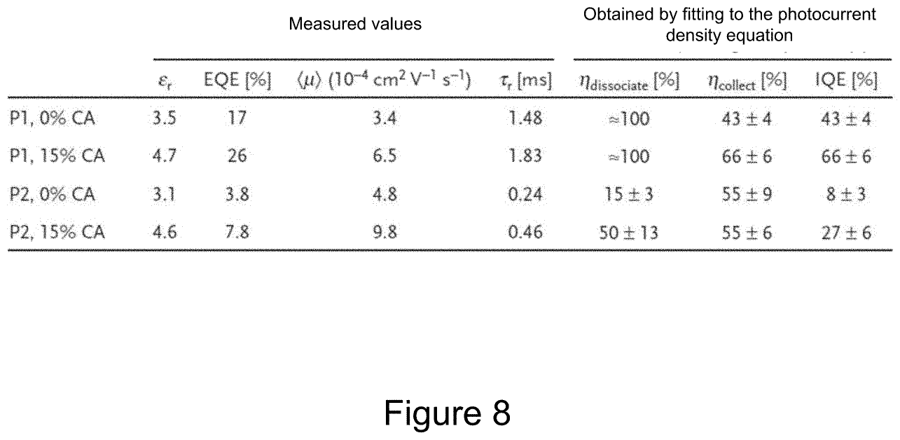

FIG. 8 is a table illustrating parameters for photodiodes with different BHJ compositions. The table lists permittivity for polymers P1 and P2, both with and without CA, EQE values, mobility values, IQE, carrier lifetimes, exciton dissociation percent values, average mobility values, and charge collection percent values. As illustrated, EQE improves by adding CA to the individual polymers. Average mobility and effective carrier lifetimes also increase by adding CA to the individual polymers. The average mobility may be determined from the TPC transit time using the relationship <μ>=d²/(V_{eff}τₜᵣₐₙₛᵢₜ). Calculated charge collection values and calculated IQE also increase by adding CA to the individual polymers. As the EQE=IQE*η_{absorb}, the BHJs show η_{absorb} is about 40%, which can be increased by light scattering or other light management optics to further optimize EQE. FIG. 8 may highlight the multiple mechanisms that may be impacted by increasing εᵣ in organic photodiodes. As illustrated, dielectric screening may promote exciton dissociation and play a role in improving charge collection.

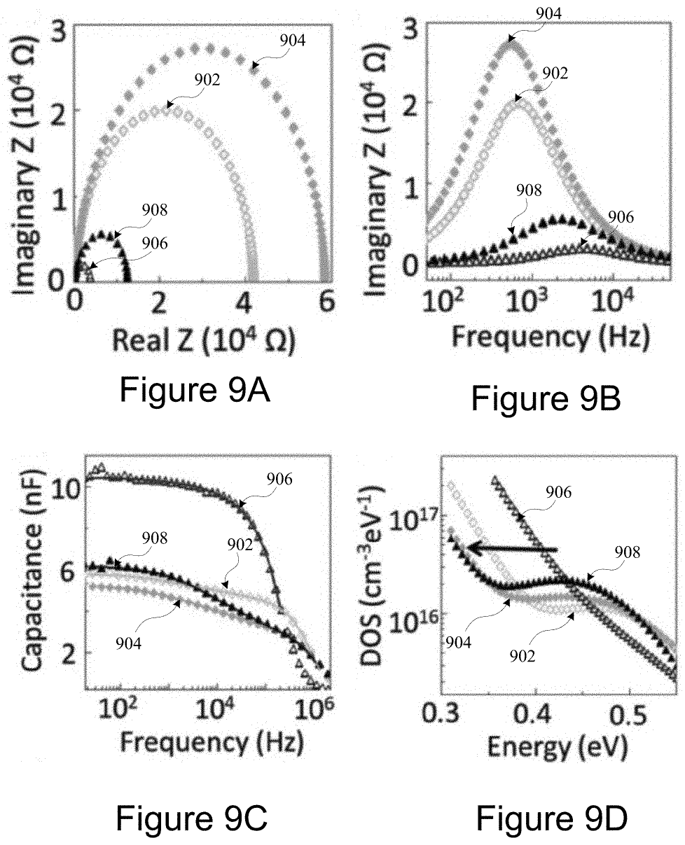

A recombination lifetime, Tr, may be estimated from electro-chemical impedance spectroscopy, as used in FIGS. 9A, 9B, 9C, and 9D. These impedance measurements may be taken in the dark, in order to put an upper boundary on Tr, and may be subject to a DC bias of about 0 V and an AC excitation of about 20 mV.

FIG. 9A is a plot illustrating real impedance and imaginary impedance for example photodiodes. Curves 902, 904, 906, and 908 represent P1 without CA, P1 with CA, P2 without CA, and P2 with CA, respectively for FIGS. 9A, 9B, 9C, and 9D. The amount of CA added may be about 15% by weight. Referring back to FIG. 9A, the plot is a Nyquist plot where the real and the imaginary components of impedance are recorded as the measurement frequency is varied.

FIG. 9B is a plot illustrating imaginary impedance and frequency for example photodiodes. FIG. 9B may be the plot of FIG. 9A displayed as imaginary impedance Im(Z) versus frequency, where the frequency corresponding to the peak Im(Z) is the inverse of the carrier lifetime by fᵣ=1/τᵣ.

FIG. 9C is a plot illustrating capacitance and frequency for example photodiodes. A sub-bandgap DOS distribution may be inferred from the capacitance versus frequency measurements of FIG. 9C. The DOS may connect the materials compositions and electronic properties, and, for example, may be used to count localized trap states. As illustrated, the carriers in states shallower than the trap energy E_{ω} can be released quickly enough to contribute to the capacitance at each measurement frequency ω. The trap energy may be related to the measurement frequency by E_{ω}=kT ln(ω₀/ω), where k may represent the Boltzmann constant, T may represent the temperature, and ω₀ may represent the rate prefactor for thermal excitation from the trap and, in some embodiments, may be assumed to be about 10¹² s⁻¹ for organic photodiodes. The trap DOS distribution may be represented as

$$D O S ( {E}_{ω} ) = - \frac{{V}_{b i}}{q A tkT} \frac{δC ( ω )}{δ l n ( w )}$$

where C(ω) may represent the capacitance measured with an ac perturbation of angular frequency ω. In one example, the built-in potential, V_{bi}, may be about 0.25 V and temperature may be about 300 K. The device area, A, may be about 9 mm². A rapid change in slope, dC/dln(ω), may indicate an increase of the trap DOS at the corresponding energy.

FIG. 9D is a plot illustrating density of states and energy from the band edge for example photodiodes.

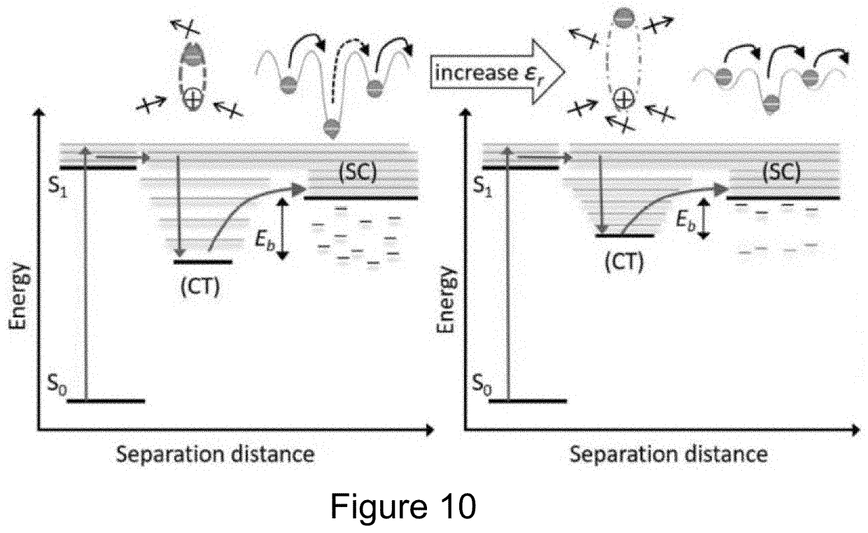

FIG. 10 illustrates example effects of dielectric screening. The schematic diagrams may illustrate the effects of dielectric screening on charge-transfer (CT) dissociation and separated charge (SC) collection. As the permittivity is increased in a BHJ, the exciton binding energy E_{b} may be reduced. The CA additive may contribute a small amount of deep traps, but the density of shallow bandtail states may be shifted to a lower energy level.

The P1 and P2 devices with about 15% CA may show better stability compared to devices without CA. Encapsulated P1 devices with CA may retain about 85% of their initial photocurrent after one month of dark storage in air, while the devices without CA may retain about 60%. Encapsulated P2 devices with CA may show about 70% of their initial photocurrent after about 15 days of dark storage in air, while the devices without CA may retain about 10%. When choosing high-permittivity additives, the additive should be able to easily blend into the BHJ without interfering with the film morphology, and the additive should show a high dielectric constant so that a small amount can increase the overall polarizability of the BHJ. Additives that satisfy these requirements will have similar effects as CA.

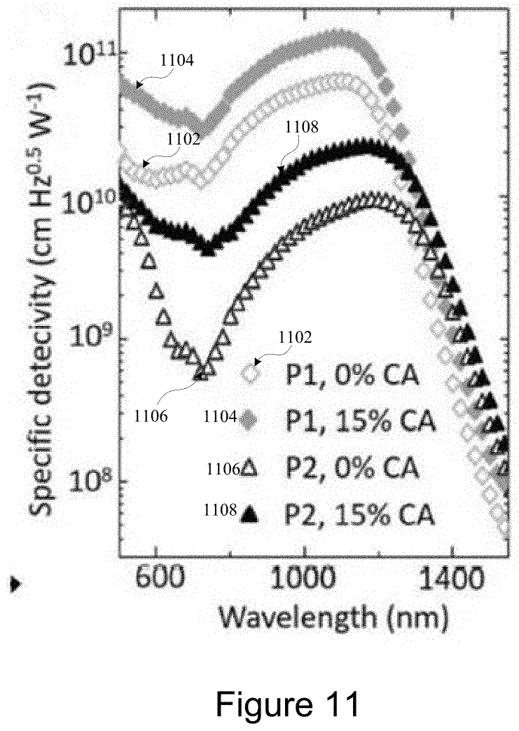

FIG. 11 is a plot illustrating specific detectivity and incident light wavelength for example photodiodes. FIG. 11 also displays the detectivity metric of our photodiodes. Curves 1102, 1104, 1106, and 1108 represent P1 without CA, P1 with CA, P2 without CA, and P2 with CA, respectively. The amount of CA added may be about 15% by weight. Detectivity is the signal-to-noise ratio and may be expressed as D*=(AΔf)^{0.5} R/iₙ, where R=EQE(λq/hc) may represent the responsivity, h may represent Planck's constant, c may represent the speed of light, A may represent the effective photodetector area, Δf may represent the detection bandwidth, and iₙ may represent the noise current measured in the dark. The detectivity at zero bias D* may reach up to about 1.2×10¹¹ Jones or cm Hz^{1/2} W⁻¹ at the peak, λ, which is about 1100 nm.

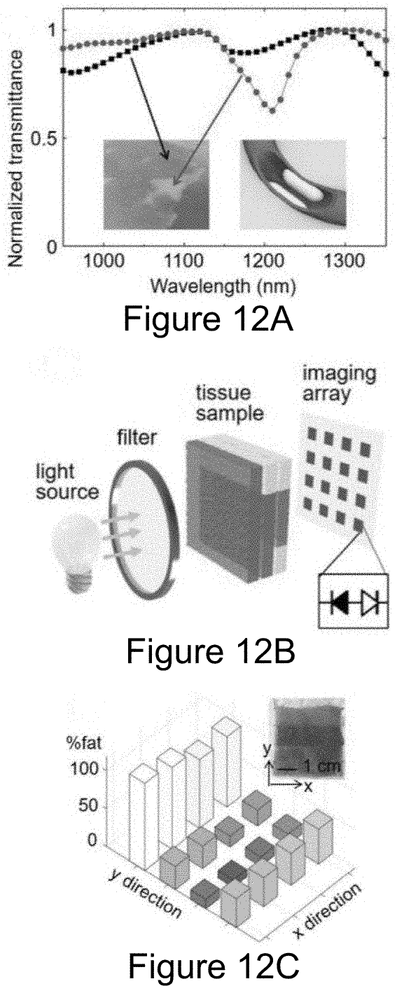

FIGS. 12A, 12B, and 12C help illustrate different uses for the presently disclosed technology. IR imaging benefits from enhanced penetration depths and accuracy with regard to minimally invasive tissue analyses. For example, since blood and fat tissues have strong absorption features in the IR, ischemia (inadequate blood flow) or atherosclerosis (fatty deposits clogging arteries) can be readily diagnosed by IR spectroscopy. It should be appreciated that other objects and materials may be analyzed with the presently disclosed technology.

FIG. 12A illustrates an example transmittance spectra of muscle and fatty tissues. FIG. 12A shows clear differences in transmittance between muscle and fat, especially at about 1210 nm. The ability to distinguish fat and muscle tissues may assist laparoscopic procedures to enhance contrast between crucial organs and surrounding tissues. The presently disclosed technology allows for a low-cost, scalable active matrix array that enables spatial mapping and compositional analysis of biological tissue.

FIG. 12B illustrates an example measurement setup, in accordance with various embodiments of the present disclosure. To enable spatial mapping, a 4×4 active matrix array may be integrated where each pixel includes an organic photodiode connected to a silicon switching diode which reduces signal cross talk between neighboring pixels. To enable compositional analysis, the incident light may be tuned to a narrow spectral range (e.g., about 10 nm of full width at half maximum) by using bandpass filters. To differentiate fatty tissues from muscle, measurements may be acquired with two wavelengths, centered at about 1152 or about 1200 nm. Fatty tissues may display much stronger absorption at about 1200 nm compared to lean muscle. Meanwhile, both types of tissues may show similar absorption at about 1152 nm. Signals may be normalized to this baseline at about 1152 nm, by calculating the transmittance ratio TR=% T_{1200 nm}/% T_{1152 nm}. This normalization also adjusts for the background due to water, because the transmittance of water is nearly constant in the range of about 1150 to about 1250 nm.

In one example, the array of photodiodes using the presently disclosed technology may be integrated with silicon rectifiers as back-to-back diodes. For each pixel, the photodiode area may be about 9 mm², and the silicon rectifiers may be soldered, or otherwise coupled onto a prototype board and then connected to photodiode electrodes by conductive epoxy or other means. The active matrix's column and row traces may use multiplexer chips that interface with the voltage source and sensors.

FIG. 12C illustrates percentage of fatty tissue at each pixel location. Three, about 1 mm thick, beef slices may be stacked together to image the fat distribution under a lean muscle layer. Faint outlines of the region with high fat content on the top quarter section may be observable in the visible spectrum. The fat buried in the bottom quarter region may be harder to see in the visible spectrum but can be distinguished by the IR TR values in FIG. 12C. The TR values may be converted to estimate the fat percentage at each pixel location by fat %=(TRₛₐₘₚₗₑ−TR_{muscle})/(TR_{fat}−TR_{muscle}). The measurement uncertainty is about 30%. Nonetheless, the organic array may be capable of providing contrast between fat and muscle tissues. The light intensity used in FIG. 12C may be about 0.3 mW cm⁻² at about 1152 nm and about 0.81 mW cm⁻² at about 1200 nm. It should be appreciated that different light intensities may be used. The transmittance percentage % T of a sample may be calculated by the relation % T=(Iₛₐₘₚₗₑ−I_{dark})/(I_{blank}−I_{dark}), where I_{dark} may represent the dark current of the pixel, Iₛₐₘₚₗₑ may represent the photocurrent measured when there is a sample between the light source and the photosensing pixel, and I_{blank} may represent the photocurrent with no sample.

One example of constructing the photodiodes is described below. Glass substrates with indium tin oxide (resistivity=15 Ωsq⁻¹) may be sequentially cleaned by ultrasonication in detergent, deionized water, and isopropanol for 15 min. Poly(3,4-ethylenedioxythiophene) polystyrene sulfonate may be mixed with isopropanol in about a 1:4 volume ratio. The solution may be spin-cast onto the clean substrates and annealed at about 130° C. for about 10 min to form about 30 nm films that serve as an interfacial layer for hole extraction. The donor P1 or P2, acceptor PC71BM, and CA additive may be dissolved in dichlorobenzene with about 3% 1,8-diiodooctane, and the blend solutions may be spin-cast to form BHJ films with thicknesses of about 110 to about 175 nm. A ZnO nanoparticle solution may be cast to form about a 10 nm film for electron extraction. Then about 100 nm Al may be deposited through thermal evaporation to complete the photodiode structure. The devices may be encapsulated with cover glass slides and glued onto the substrates with epoxy to allow characterization in ambient conditions. IT should be appreciated that different methods may be used to deposit the materials, different concentrations may be used for individual materials, and different materials may be substituted for the example materials listed above.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the technology disclosed herein. Also, a multitude of different constituent components and component names other than those depicted herein can be applied to the various partitions.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the terms “component” or “component” does not imply that the components or functionality described or claimed as part of the component are all configured in a common package. Indeed, any or all of the various components of a component, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A shortwave infrared organic photodiode comprising:
a substrate layer;
a first electrode layer, the first electrode layer disposed on the substrate layer;
a first interfacial layer, the first interfacial layer disposed on the first electrode layer;
a bulk heterojunction, the bulk heterojunction disposed on the first interfacial layer, wherein the bulk heterojunction comprises an additive with a dielectric constant above a threshold value;
a second interfacial layer, the second interfacial layer disposed on the bulk heterojunction; and
a second electrode layer, the second electrode layer disposed on the second interfacial layer.

2. The photodiode of claim 1, wherein the additive is one or more of an organic material, dissolvable in a polymer solution, and an insulator or a semiconductor.

3. The photodiode of claim 1, wherein the additive is camphoric acid anyhdrate.

4. The photodiode of claim 1, wherein the amount of additive used in the bulk heterojunction is between about 5% to about 25% by weight.

5. The photodiode of claim 4, wherein the amount of additive used in the bulk heterojunction is between about 10% to about 15% by weight.

6. The photodiode of claim 1, wherein the bulk heterojunction further comprises:
a donor polymer; and
an acceptor.

7. The photodiode of claim 6, wherein the donor polymer comprises sulfur.

8. The photodiode of claim 6, wherein the donor polymer comprises selenium.

9. The photodiode of claim 6, wherein the acceptor molecules comprise a fullerene-derivative PCBM.

10. The photodiode of claim 6, wherein the donor polymer comprises a side chain of ethylene glycol.

11. The photodiode of claim 1, wherein a relative permittivity value for the bulk heterojunction is greater than or equal to about 4.

12. A shortwave infrared organic photodiode comprising:
a bulk heterojunction, wherein the bulk heterojunction comprises:
an additive with a dielectric constant above a threshold value;
a donor polymer; and
an acceptor.

13. The photodiode of claim 12, wherein the additive is one or more of an organic material, dissolvable in a polymer solution, and an insulator or a semiconductor.

14. The photodiode of claim 12, wherein the additive is camphoric acid anhydrate.

15. The photodiode of claim 12, wherein the amount of additive used in the bulk heterojunction is between about 10% to about 15% by weight.

16. The photodiode of claim 12, wherein the donor polymer comprises sulfur.

17. The photodiode of claim 12, wherein the donor polymer comprises selenium.

18. The photodiode of claim 12, wherein the acceptor molecules comprise a fullerene-derivative PCBM.

19. The photodiode of claim 12, wherein the donor polymer comprises a side chain of ethylene glycol.

20. The photodiode of claim 12, wherein a relative permittivity value for the bulk heterojunction is greater than or equal to about 4.
